(19) United States
(12) Patent Application Publication
(10) Pub. No.: US 2025/0374690 A1
(43) Pub. Date: Dec. 4, 2025

(54) IMAGE SENSOR

(71) Applicant: SAMSUNG ELECTRONICS CO., LTD., Suwon-si (KR)

(72) Inventors: Youngrae Kim, Suwon-si (KR); DOOSIK SEOL, Suwon-si (KR)

(73) Assignee: SAMSUNG ELECTRONICS CO., LTD., Suwon-si (KR)

(21) Appl. No.: 19/072,427

(22) Filed: Mar. 6, 2025

(30) Foreign Application Priority Data
May 29, 2024 (KR) 10-2024-0070397

(51) Int. Cl. H10F 39/00

(52) U.S. Cl. CPC H10F 39/802; H10F 39/807

(57) ABSTRACT

An image sensor is provided. The image sensor includes: a substrate including a first region in which a photoelectric conversion region is provided, and a second region in which a first device active region and a second device active region are arranged along a first direction; a first gate electrode provided on the first device active region; a second gate electrode provided on the second device active region; and a first connecting conductive pattern provided between the first gate electrode and the second gate electrode. A distance between the first gate electrode and the second gate electrode increases along a second direction perpendicular to the first direction.

### CROSS-REFERENCE TO RELATED APPLICATION

The application claims priority under 35 U.S.C. § 119 to Korean Patent Application No. 10-2024-0070397, filed on May 29, 2024, in the Korean Intellectual Property Office, the disclosure of which is incorporated by reference herein in its entirety.

### BACKGROUND

The present disclosure relates to an image sensor.

An image sensor is a device that converts optical image signals into electrical signals and includes types such as charge coupled device (CCD) image sensors and complementary metal oxide semiconductor (CMOS) image sensors. The image sensor includes multiple pixels. Each pixel includes a light-receiving area that receives incident light and converts it into an electrical signal, and a pixel circuit that uses the charge generated in the light-receiving area to output a pixel signal.

The pixel circuit includes multiple transistors. As the integration density of image sensors increases, the transistors in the pixel circuit are also being miniaturized. As transistors become smaller, the problem of increased noise occurs.

### SUMMARY

One or more example embodiments provide an image sensor with reduced noise.

According to an aspect of an example embodiment, an image sensor includes: a substrate including a first region in which a photoelectric conversion region is provided, and a second region in which a first device active region and a second device active region are arranged along a first direction; a first gate electrode provided on the first device active region; a second gate electrode provided on the second device active region; and a first connecting conductive pattern provided between the first gate electrode and the second gate electrode. A distance between the first gate electrode and the second gate electrode increases along a second direction perpendicular to the first direction.

According to an aspect of another example embodiment, an image sensor includes: a plurality of photoelectric conversion regions arranged along intersecting first and second directions; a plurality of transfer gate electrodes provided on the plurality of photoelectric conversion regions, respectively; a plurality of floating diffusion regions adjacent to the plurality of transfer gate electrodes, respectively; first and second source follower transistors arranged along the first direction; and a first connecting conductive pattern provided between the first source follower transistor and the second source follower transistor, and electrically connecting a first gate electrode of the first source follower transistor and a second gate electrode of the second source follower transistor. A distance between the first gate electrode and the second gate electrode increases along the second direction. Drains of the first source follower transistor and the second source follower transistor are provided between the first gate electrode and the second gate electrode, and are electrically connected to the plurality of floating diffusion regions. Sources of the first source follower transistor and the second source follower transistor are spaced apart from the drains with the first gate electrode and the second gate electrode therebetween, respectively.

According to an aspect of another example embodiment, an image sensor includes: a plurality of pixels arranged along intersecting first and second directions; first and second source follower transistors configured to be controlled by a gate voltage that is based on charge carriers provided from the plurality of pixels; and a connecting conductive pattern provided between the first and second source follower transistors, and electrically connecting gate electrodes of the first and second source follower transistors. A distance between the gate electrodes of the first and second source follower transistors increases along the second direction. Drains of the first and second source follower transistors are provided between the gate electrodes. Sources of the first and second source follower transistors are spaced apart from the drains with the gate electrodes therebetween, respectively.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages will be more apparent from the following description of example embodiments, taken in conjunction with the accompanying drawings, in which:

FIG. 1 is a block diagram of an image sensor according to an example embodiment.

FIG. 2 is a plan view of the pixel array of FIG. 1.

FIG. 3 is an equivalent circuit diagram of a pixel group of FIG. 1.

FIG. 4A is a plan view of an image sensor according to example embodiments.

FIG. 4B is a cross-sectional view taken along line A-A′ of FIG. 4A.

FIG. 4C is a cross-sectional view taken along line B-B′ of FIG. 4A.

FIG. 4D is a cross-sectional view taken along line C-C′ of FIG. 4A.

FIG. 4E is a cross-sectional view taken along line D-D′ of FIG. 4A.

FIG. 4F is a cross-sectional view taken along line E-E′ of FIG. 4A.

FIG. 4G is a plan view for explaining the pixel active region, device active region, first gate electrode, and second gate electrode of FIG. 4A.

FIG. 5A is a plan view of an image sensor according to example embodiments.

FIG. 5B is a plan view for explaining the pixel active region, device active region, first gate electrode, and second gate electrode of FIG. 5A.

FIG. 6A is a plan view of an image sensor according to example embodiments.

FIG. 6B is a plan view for explaining the pixel active region, device active region, first gate electrode, and second gate electrode of FIG. 6A.

FIG. 7A is a plan view of an image sensor according to example embodiments.

FIG. 7B is a plan view for explaining the pixel active region, device active region, first gate electrode, and second gate electrode of FIG. 7A.

FIG. 8A is a plan view of an image sensor according to example embodiments.

FIG. 8B is a plan view for explaining the pixel active region, device active region, first gate electrode, and second gate electrode of FIG. 8A.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

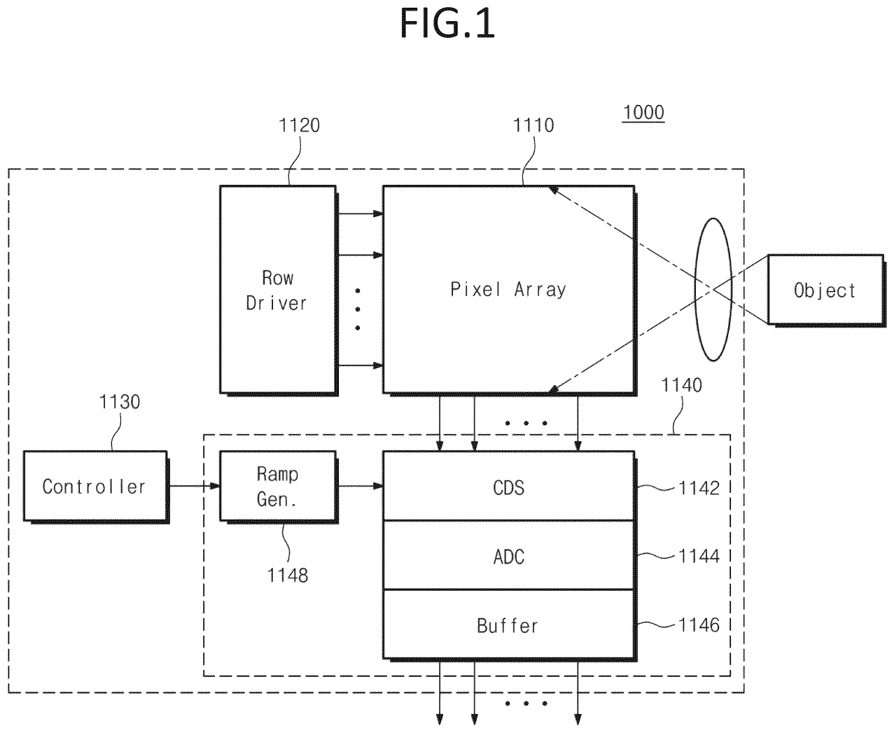

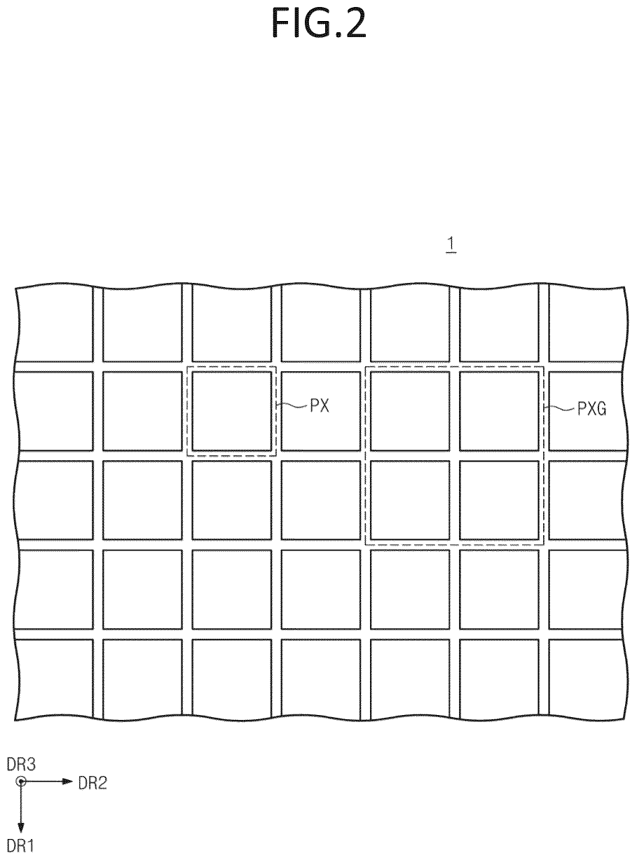

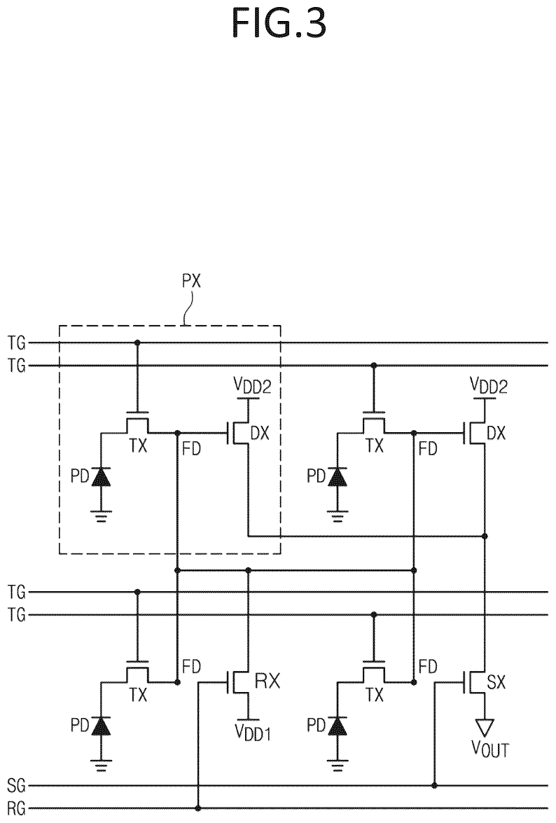

FIG. 1 is a block diagram of an image sensor according to an example embodiment. FIG. 2 is a plan view of the pixel array of FIG. 1. FIG. 3 is an equivalent circuit diagram of a pixel group of FIG. 1.

Referring to FIGS. 1 to 3, an image sensor 1000 may be provided. The image sensor 1000 may be mounted in an electronic device with image or light sensing functions. For example, the image sensor 1000 may be mounted in electronic devices such as cameras, smartphones, wearable devices, Internet of Things (IoT), tablet PCs, PDAs (Personal Digital Assistants), PMPs (Portable Multimedia Players), navigation devices, etc. The image sensor 1000 may be mounted in electronic devices provided as components in vehicles, furniture, manufacturing equipment, doors, various measuring instruments, etc.

The image sensor 1000 may include a pixel array 1110, a controller 1130, a row driver 1120, and a pixel signal processor 1140 as a control unit.

The pixel array 1110 may include a plurality of pixels arranged two-dimensionally along a first direction DR1 and a second direction DR2. The plurality of pixels may be arranged in a certain pattern to generate a high-quality image. For example, the plurality of pixels may be arranged in a Bayer pattern or chess mosaic pattern. When the plurality of pixels have a Bayer pattern, the pixels in the pixel array 1110 may each receive red, green, and blue light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or a combination thereof. The output voltage of the plurality of pixels may be determined based on the generated charge carriers. The pixel array 1110 may include a pixel group PXG. The pixel group PXG may be a collection of pixels PX that share a reset transistor RX, a select transistor SX, and a source follower transistor source follower transistor DX. As an example, the pixel group PXG is shown to include of 4 pixels PX. In other examples, the pixel group PXG may include fewer or more than 4 pixels PX. The number of reset transistors RX, select transistors SX, and source follower transistors DX shared by the pixel group PXG may be determined as needed.

The pixel array 1110 may be driven according to multiple driving signals including row selection signals, reset signals, charge transfer signals, etc., which may be provided from the row driver 1120 and received by the pixel array 1110. The row driver 1120 may provide multiple driving signals to the pixel array 1110 to drive the multiple pixels. In example embodiments, the driving signals may be provided on a row-by-row basis of the pixel array 1110. The pixels belonging to one row of the pixel array 1110 selected by the driving signals of the row driver 1120 may be simultaneously activated by the signals output from the row driver 1120. The pixels belonging to the selected row may provide output voltages corresponding to the absorbed light to the corresponding column output lines. In example embodiments, the pixels may provide output voltages one row at a time. The output voltages may be provided to the correlated double sampler 1142.

The pixel signal processor 1140 may include a correlated double sampler (CDS) 1142, an analog-to-digital converter (ADC) 1144, and a buffer 1146. The correlated double sampler 1142 may sample and hold the output voltages provided by the pixel array 1110. The correlated double sampler 1142 may reduce noise and improve the signal-to-noise ratio (SNR). The correlated double sampler 1142 may be configured to remove noise voltage from the pixel's output voltage. For example, the correlated double sampler 1142 may double-sample a specific noise level and a signal level due to the output signal, and output a difference level corresponding to the difference between the noise level and the signal level. The correlated double sampler 1142 may receive a ramp signal generated by a ramp signal generator 1148, compare the ramp signal with the input, and output the comparison result.

The analog-to-digital converter 1144 may convert the analog signal corresponding to the difference level received from the correlated double sampler 1142 into a digital signal. The buffer 1146 may latch the digital signal. The latched digital signal may be sequentially output to the outside of the image sensor 1100 and transferred to an image processor.

The controller 1130 may control the row driver 1120 to control the pixel array 1110 to absorb light and accumulate charge carriers, temporarily store the accumulated charges, and output electrical signals corresponding to the stored charges to the outside of the pixel array 1110. Additionally, the controller 1130 may control the pixel signal processor 1140 to measure the output voltage provided by the pixel array 1110.

Each of the plurality of pixels PX may include a photoelectric conversion device PD, a transfer transistor TX, and a floating diffusion region FD. The photoelectric conversion device PD may generate and accumulate photocharges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated in the photoelectric conversion device to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate. The charge carriers generated in the photoelectric conversion device may move to the floating diffusion region FD along the channel between the photoelectric conversion device PD and the floating diffusion region FD. The drain terminal of the transfer transistor TX may be electrically connected to the floating diffusion region FD, and the source terminal may be electrically connected to the photoelectric conversion device PD.

The floating diffusion region FD may receive and accumulate charges transferred from the photoelectric conversion device PD. The source follower transistor DX may be controlled according to the amount of charge accumulated in the floating diffusion region FD. The gate terminal of the source follower transistor DX may be electrically connected to the floating diffusion region FD, the drain terminal may be supplied with a second power voltage VDD2, and the source terminal may be electrically connected to the drain terminal of the select transistor SX. The source follower transistor DX may be a source follower buffer amplifier that outputs current proportional to the amount of charge in the floating diffusion region FD.

The reset transistor RX may periodically reset the charges accumulated in the floating diffusion region FD. The gate terminal of the reset transistor RX may be electrically connected to the reset signal line RG. The drain terminal of the reset transistor RX is connected to the floating diffusion region FD and the source terminal is connected to a first power voltage VDD1. In an example embodiment, the first power voltage VDD1 may be substantially the same as the second power voltage VDD2. When the reset transistor RX is turned on, the first power voltage VDD1 connected to the source terminal of the reset transistor RX is transferred to the floating diffusion region FD. When the reset transistor RX is turned on, the charges accumulated in the floating diffusion region FD may be discharged, resetting the floating diffusion region FD. When the charge carriers are electrons, the voltage of the floating diffusion region FD may decrease as electrons accumulate in the floating diffusion region FD. When the reset transistor RX is turned on, electrons in the floating diffusion region FD are discharged externally, and the voltage of the floating diffusion region FD may rise to the first power voltage VDD1. As the first power voltage VDD1 is applied to the floating diffusion region FD, the first power voltage VDD1 is applied to the gate terminal of the source follower transistor DX, which can reset the output of the source follower transistor DX.

The select transistor SX may select the plurality of pixels PX on a row-by-row basis. The select transistor SX may transfer the current generated in the source follower transistor DX of each of the selected pixels to the output line. The drain terminal, source terminal, and gate terminal of the select transistor SX may be electrically connected to the source terminal of the source follower transistor DX, the output line, and the row select line SG, respectively. a select control signal applied from the row select line SG to the gate terminal of the select transistor SX may cause the signal generated by the source follower transistor DX to be output to the output line.

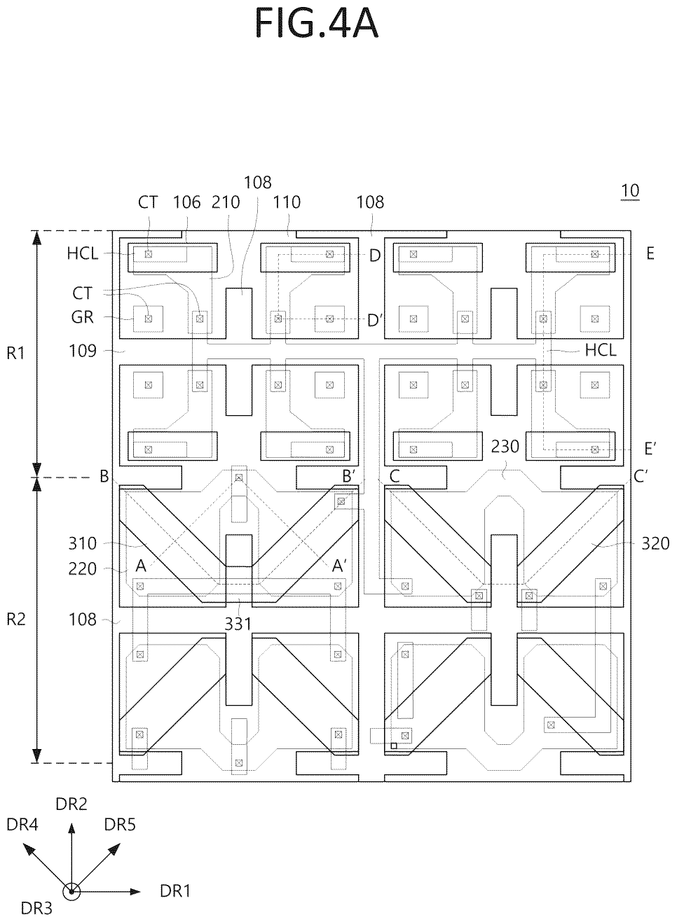

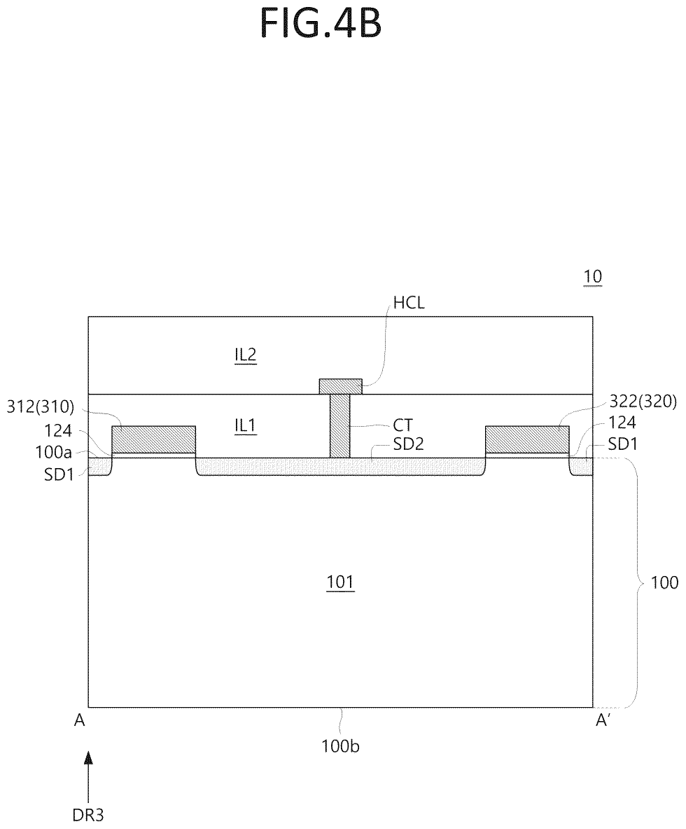

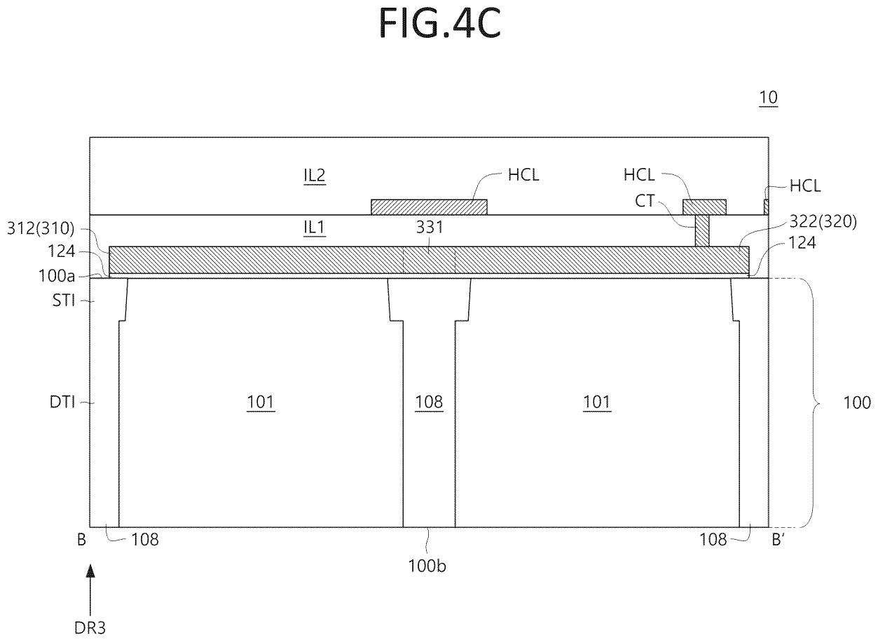

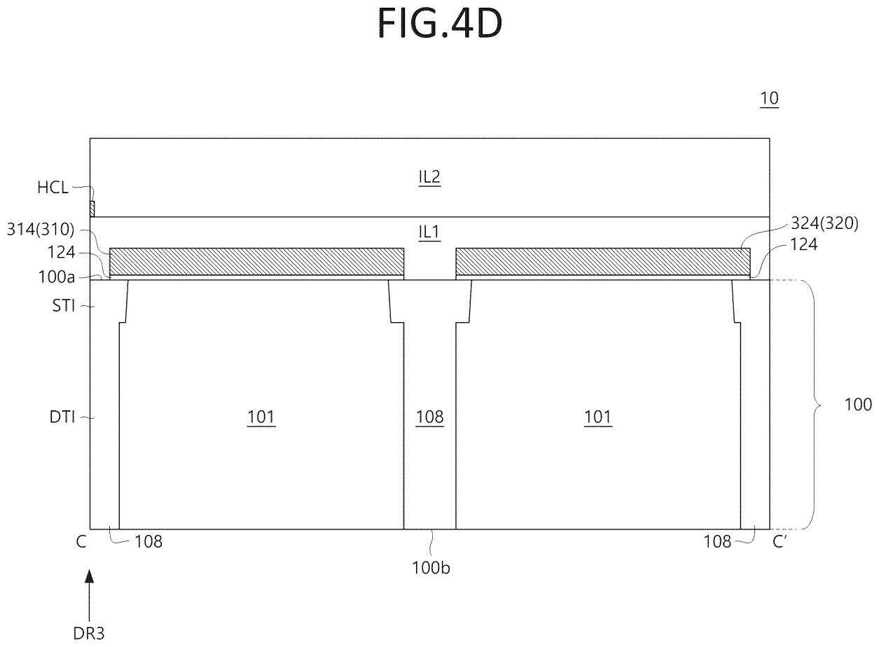

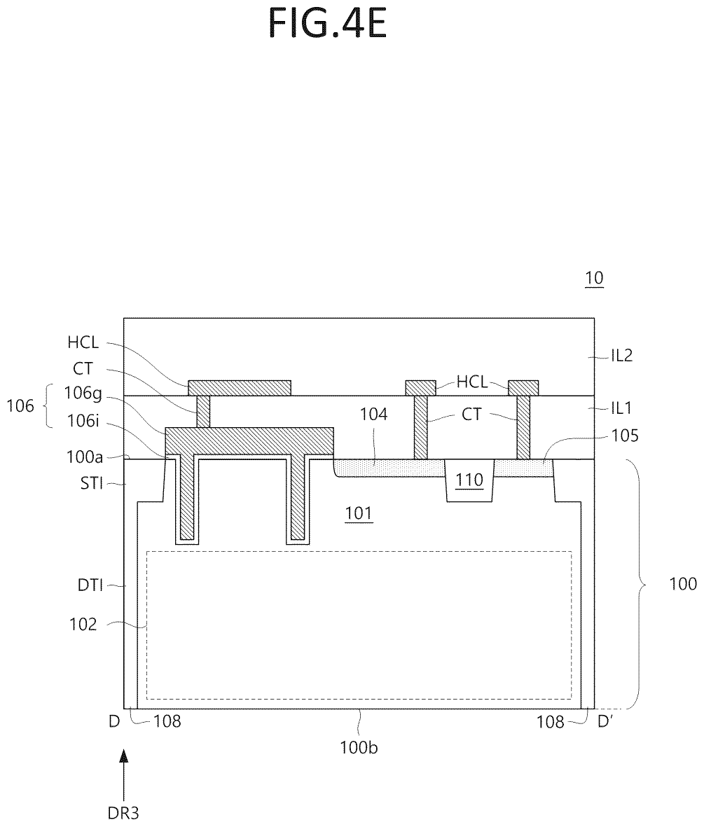

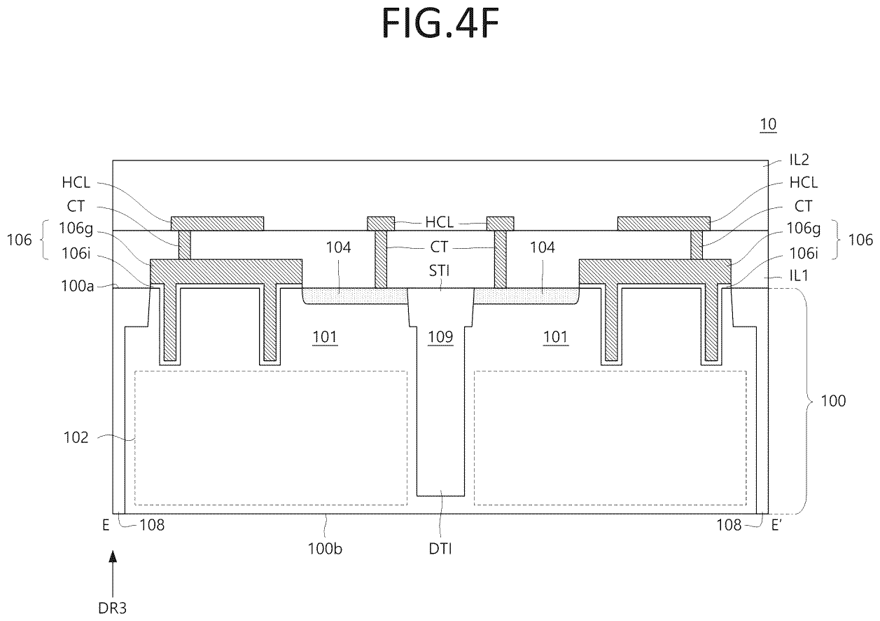

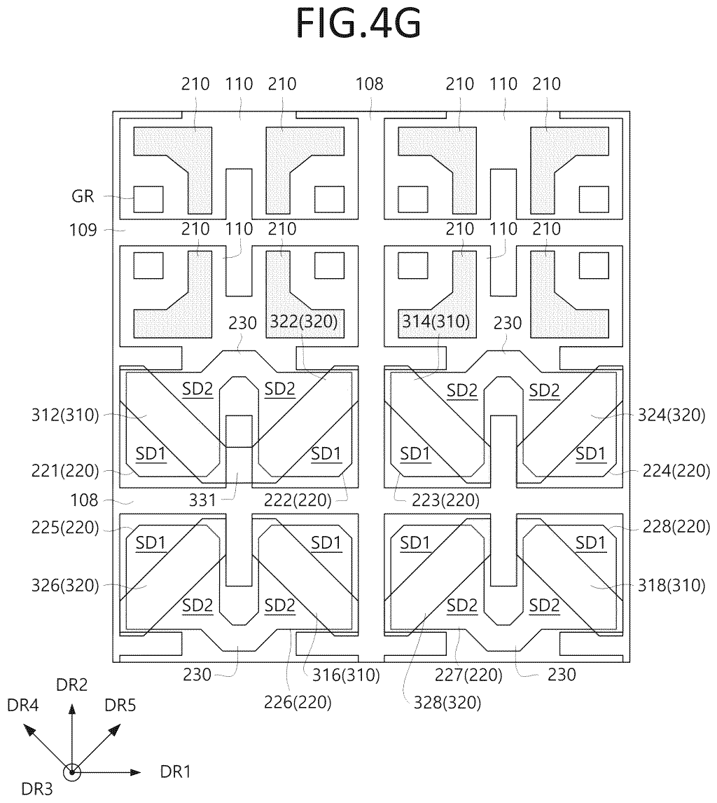

FIG. 4A is a plan view of an image sensor according to example embodiments.

FIG. 4B is a cross-sectional view taken along line A-A′ of FIG. 4A. FIG. 4C is a cross-sectional view taken along line B-B′ of FIG. 4A. FIG. 4D is a cross-sectional view taken along line C-C′ of FIG. 4A. FIG. 4E is a cross-sectional view taken along line D-D′ of FIG. 4A. FIG. 4F is a cross-sectional view taken along line E-E′ of FIG. 4A. FIG. 4G is a plan view for explaining the pixel active region, device active region, first gate electrode, and second gate electrode of FIG. 4A.

Referring to FIGS. 4A to 4G, a substrate 100 may be provided. The substrate 100 may include a semiconductor region 101, a first isolation layer 108, a second isolation layer 109, and a third isolation layer 110. The substrate 100 may include a first surface 100a and a second surface 100b facing opposite directions. The first surface 100a and the second surface 100b may extend along the first direction DR1 and the second direction DR2. The first surface 100a and the second surface 100b may be spaced apart from each other along the third direction DR3. For example, the first to third directions DR1 to DR3 may be perpendicular to each other. The substrate 100 may include a first region R1 and a second region R2. Pixel active regions 210, photoelectric conversion regions 102, transfer gate structures 106, and floating diffusion regions 104 may be arranged in the first region R1. Device active regions 220, connection regions 230, reset transistors, source follower transistors, and select transistors may be arranged in the second region R2.

The semiconductor region 101 may include a semiconductor material. For example, the semiconductor region 101 may include silicon (Si), germanium (Ge), or silicon-germanium (SiGe). The semiconductor region 101 may have a first conductivity type. For example, the first conductivity type may be p-type or n-type. When the conductivity type of the semiconductor region 101 is p-type, the semiconductor region 101 may be a silicon (Si) substrate including impurities of group III elements (for example, boron (B), aluminum (Al), gallium (Ga), indium (In), etc.) or group II elements. Hereinafter, regions with p-type conductivity may include impurities of group II or III elements. When the conductivity type of the substrate 100 is n-type, it may be a silicon (Si) substrate including impurities of group V elements (for example, phosphorus (P), arsenic (As), antimony (Sb), etc.), group VI, or group VII elements. Hereinafter, regions with n-type conductivity may include impurities of group V, VI, or VII elements. Hereinafter, impurities that make the semiconductor region 101 have the first conductivity type and the second conductivity type may be referred to as first impurities and second impurities, respectively. When the first conductivity type is p-type or n-type, the second conductivity type may be n-type or p-type, respectively. The semiconductor region 101 may be an epi layer formed by an epitaxial growth process.

The first isolation layer 108 may be provided on the side of the semiconductor region 101. The first isolation layer 108 may be provided between immediately adjacent pixel active regions 210 along the first direction DR1, between immediately adjacent device active regions 220, and between immediately adjacent pixel active region 210 and device active region 220. The first isolation layer 108 may extend along the third direction DR3. The first isolation layer 108 may extend from the second surface 100b to the first surface 100a. The first isolation layer 108 may include a deep trench isolation (DTI) and a shallow trench isolation (STI) arranged in order along the third direction DR3. The STI may include an electrically insulating material. For example, the STI may include silicon nitride, silicon oxide, silicon oxynitride, or a combination thereof. In example embodiments, the STI may be wider than the DTI along the first direction DR1 and the second direction DR2.

The DTI may prevent or reduce electrical crosstalk phenomenon that degrades the signal-to-noise ratio due to charge carrier exchange between adjacent pixels. For example, the DTI may include a conductive material (e.g., doped polysilicon, metal, metal silicide, metal nitride, or at least one metal-containing material), an insulating material (e.g., silicon-based insulating material (e.g., silicon nitride, silicon oxide, and/or silicon oxynitride), or a high-k material (e.g., metal oxide including at least one metal selected from the group consisting of hafnium (Hf), zirconium (Zr), aluminum (Al), tantalum (Ta), titanium (Ti), yttrium (Y) and lanthanides (La))). In example embodiments, the sidewalls of the DTI may be doped with a material with high reflectivity to prevent or reduce optical crosstalk phenomenon where light is detected in pixels adjacent to the pixel where the light is incident. For example, the material with high reflectivity may be boron. When the DTI includes a conductive material, for example, a negative fixed charge layer may be provided between the DTI and the semiconductor region 101. The negative fixed charge layer may include, for example, a metal oxide including at least one metal selected from the group consisting of hafnium (Hf), zirconium (Zr), aluminum (Al), tantalum (Ta), titanium (Ti), yttrium (Y) and lanthanides (La).

The second isolation layer 109 may be provided on the side of the semiconductor region 101. In example embodiments, the second isolation layer 109 may extend along the first direction DR1 between pixel active regions 210 immediately adjacent to each other along the second direction DR2. The second isolation layer 109 and the first isolation layer 108 may surround the semiconductor region 101. The second isolation layer 109 may extend along the third direction DR3. Unlike the first isolation layer 108, the second isolation layer 109 may extend from the first surface 100a to a depth shallower than the second surface 100b. The semiconductor region 101 may be located between the second isolation layer 109 and the second surface 100b. This can prevent deterioration of the electrical characteristics of the image sensor 10. The second isolation layer 109 may include a DTI and a STI arranged in order along the third direction DR3. The STI may be wider than the DTI along the first direction DR1 and the second direction DR2.

The third isolation layer 110 may be provided on the semiconductor region 101. The third isolation layer 110 may include a STI. In example embodiments, the STI included in the first isolation layer 108 and the second isolation layer 109 and the STI included in the third isolation layer 110 may be formed by substantially the same process. For example, a part of the STI formed in one process may be included in the first isolation layer 108 and the second isolation layer 109 adjacent to the first surface 100a, and another part of the STI may be included in the third isolation layer 110. The third isolation layer 110 may include an electrically insulating material. For example, the third isolation layer 110 may include silicon nitride, silicon oxide, silicon oxynitride, or a combination thereof.

The first isolation layer 108, the second isolation layer 109, and the third isolation layer 110 may define pixel active regions 210 and ground regions GR in the first region R1. The pixel active regions 210 and the ground regions GR may be semiconductor regions 101 exposed between the first isolation layer 108, the second isolation layer 109, and the third isolation layer 110 in the first region R1. The pixel active regions 210 and the ground regions GR may overlap with the photoelectric conversion regions 102 along the third direction DR3. The pixel active regions 210 may be arranged in a 2×4 format. For example, the first region R1 may include two pixel active regions 210 along the second direction DR2 and four pixel active regions 210 along the first direction DR1; and the second region R2 may include two pixel active regions 210 along the second direction DR2 and four pixel active regions 210 along the first direction DR1. Each of the pixel active regions 210 may include a portion extending in the first direction DR1 and a portion extending in the second direction DR2. Pixel active regions 210 immediately adjacent to each other along the first direction DR1 may be symmetrical with respect to an imaginary axis extending along the second direction DR2. Pixel active regions 210 immediately adjacent to each other along the second direction DR2 may be symmetrical with respect to an imaginary axis extending along the first direction DR1.

The ground region 105 may be provided on the top of the semiconductor region 101. The ground region 105 may be provided in the first region R1. The ground region 105 may have the second conductivity type. The ground region 105 may be formed by injecting the second impurity into the semiconductor region 101. The ground region 105 may be spaced apart from the photoelectric conversion region 102. The ground region 105 may be configured to apply a ground voltage to the semiconductor region 101.

The photoelectric conversion region 102 may be formed in the semiconductor region 101 surrounded by the first isolation layer 108 in the first region R1. In example embodiments, the photoelectric conversion region 102 may include at least one photodiode. For example, the photoelectric conversion region 102 may include a pn photodiode. When the conductivity type of the semiconductor region 101 is p-type, the p-type region of the photoelectric conversion region 102 may be the semiconductor region 101, and the n-type region may be formed by injecting the second impurity into the semiconductor region 101. In example embodiments, the photoelectric conversion region 102 may include multiple pn junctions located at different depths. When light is incident on the photoelectric conversion region 102, electron-hole pairs (EHPs) may be generated in the photoelectric conversion region 102. For example, electron-hole pairs may be generated in the depletion region formed adjacent to the pn junction. The stronger the intensity of light incident on the photoelectric conversion region 102, the more electron-hole pairs may be generated. When a reverse bias is applied to the photoelectric conversion region 102, charge carriers (electrons or holes) may accumulate in the photoelectric conversion region 102. The charge carriers accumulated in the photoelectric conversion region 102 may move to the floating diffusion region 104 by the voltage applied to the transfer gate electrode 106g.

The floating diffusion region 104 may be provided in the pixel active region 210. The floating diffusion region 104 may be provided on the top of the semiconductor region 101. The floating diffusion region 104 may have the second conductivity type. In example embodiments, the floating diffusion region 104 may be formed by injecting the second impurity into the semiconductor region 101. The floating diffusion region 104 may be spaced apart from the photoelectric conversion region 102. The region between the floating diffusion region 104 and the photoelectric conversion region 102 may have the first conductivity type. When the required voltage is applied to the transfer gate electrode 106g, the floating diffusion region 104 may receive and accumulate charge carriers provided from the photoelectric conversion region 102.

The transfer gate structures 106 may be provided on each of the pixel active regions 210. The transfer gate structure 106 may be adjacent to the floating diffusion region 104 and the photoelectric conversion region 102. The transfer gate structure 106 may include an upper part provided on the first surface 100a and a lower part inserted into the semiconductor region 101. In example embodiments, the transfer gate structure 106 may include one part, two parts, three parts or more than three parts. As an example, the transfer gate structure 106 may include a pair of lower parts (i.e., two parts). The transfer gate structure 106 may be referred to as a vertical transfer gate (VTG). The transfer gate structure 106 may include a transfer gate electrode 106g and a transfer gate insulating film 106i.

The transfer gate insulating film 106i may extend along the surface of the semiconductor region 101. The transfer gate insulating film 106i may be configured to electrically separate the transfer gate electrode 106g and the semiconductor region 101. For example, the transfer gate insulating film 106i may include a silicon-based insulating material (e.g., silicon nitride, silicon oxide, and/or silicon oxynitride) or a high-k material (e.g., a metal oxide including at least one metal selected from the group consisting of hafnium (Hf), zirconium (Zr), aluminum (Al), tantalum (Ta), titanium (Ti), yttrium (Y), and lanthanides (La)).

The transfer gate electrode 106g may be provided on the transfer gate insulating film 106i. The transfer gate electrode 106g may be spaced apart from the semiconductor region 101 by the transfer gate insulating film 106i. The transfer gate electrode 106g may include an electrically conductive material. For example, the transfer gate electrode 106g may include doped polysilicon or metal (e.g., copper (Cu), aluminum (Al), molybdenum (Mo), platinum (Pt), titanium (Ti), tantalum (Ta), tungsten (W), or a combination thereof).

The transfer gate structure 106, the photoelectric conversion region 102, and the floating diffusion region 104 may constitute a transfer transistor. The transfer gate structure 106, the photoelectric conversion region 102, and the floating diffusion region 104 may be included in the gate, the source, and the drain of the transfer transistor, respectively. When voltage is applied to the transfer gate electrode 106g, a channel of the second conductivity type may be formed in the region of the semiconductor region 101 adjacent to the transfer gate structure 106. The channel may be configured to move charge carriers generated in the photoelectric conversion region 102 to the floating diffusion region 104. When no voltage is applied to the transfer gate electrode 106g, charge carriers generated in the photoelectric conversion region 102 may accumulate within the photoelectric conversion region 102.

The first isolation layer 108, second isolation layer 109, and third isolation layer 110 may define a device active region 220 and a connection region 230 in the second region R2. The device active region 220 and connection region 230 may be semiconductor regions 101 exposed between the first isolation layer 108, the second isolation layer 109, and the third isolation layer 110 in the second region R2. The device active regions 220 may be arranged in a 2×4 format. The device active regions 220 may include a (1,1) device active region 221(220), a (1,2) device active region 222(220), a (2,1) device active region 223(220), a (2,2) device active region 224(220), a (3,1) device active region 225(220), (3,2) device active region 226(220), a (4,1) device active region 227(220), and a (4,2) device active region 228(220). The (1,1) to (2,2) device active regions 221 to 224 may be arranged along the first direction DR1. The (3,1) to (4,2) device active regions 225 to 228 may be arranged along the first direction DR1. The (1,1) to (2,2) device active regions 221 to 224 may each be spaced apart from the (3,1) to (4,2) device active regions 225 to 228 along the second direction DR2.

The connection region 230 may be provided between a pair of device active regions 220 immediately adjacent to each other along the first direction DR1, connecting the pair of device active regions 220. The connection regions 230 may be provided between the (1,1) device active region 221(220) and the (1,2) device active region 222(220), between the (2,1) device active region 223(220) and the (2,2) device active region 224(220), between the (3,1) device active region 225(220) and the (3,2) device active region 226(220), and between the (4,1) device active region 227(220) and the (4,2) device active region 228(220), respectively. The connection region 230 may have a shape where its middle portion is bent outward from the region between the pair of device active regions 220. At least a portion of the connection region 230 may be spaced apart from regions overlapping with the pair of device active regions 220 along the first direction DR1. In example embodiments, the connection region 230 may have the second conductivity type.

One part of the connection region 230 between the (1,1) device active region 221(220) and the (1,2) device active region 222(220) may extend from the (1,1) device active region 221(220) in a direction combining the first direction DR1 and the second direction DR2. Other part of the connection region 230 between the (1,1) device active region 221(220) and the (1,2) device active region 222(220) may extend from the (1,2) device active region 221(220) in a direction combining the opposite direction of the first direction DR1 and the second direction DR2. Another part of the connection region 230 between the (1,1) device active region 221(220) and the (1,2) device active region 222(220) may extend in the first direction DR1 to connect the one part and the other part. The connection region 230 between the (2,1) device active region 223(220) and the (2,2) device active region 224(220) may have substantially the same shape as the connection region 230 between the (1,1) device active region 221(220) and the (1,2) device active region 222(220).

One part of the connection region 230 between the (3,1) device active region 225(220) and the (3,2) device active region 226(220) may extend from the (3,1) device active region 225(220) in a direction combining the first direction DR1 and the opposite direction of the second direction DR2. Other part of the connection region 230 between the (3,1) device active region 225(220) and the (3,2) device active region 226(220) may extend from the (3,2) device active region 221(220) in a direction combining the opposite direction of the first direction DR1 and the opposite direction of the second direction DR2. Another part of the connection region 230 between the (3,1) device active region 225(220) and the (3,2) device active region 226(220) may extend in the first direction DR1 to connect the one part and the other part. The connection region 230 between the (4,1) device active region 227(220) and the (4,2) device active region 228(220) may have substantially the same shape as the connection region 230 between the (3,1) device active region 225(220) and the (3,2) device active region 226(220).

First gate electrodes 310 and second gate electrodes 320 may be provided on the device active regions 220. The first gate electrode 310 and the second gate electrode 320 may be provided on each of the pair of device active regions 220 connected by the connection region 230. The first gate electrodes 310 may extend along a fourth direction DR4 intersecting the first direction DR1 and the second direction DR2. The fourth direction DR4 may be diagonal to the first direction DR1 and the second direction DR2. The fourth direction DR4 may be parallel to the first surface 100a. The second gate electrodes 320 may extend along a fifth direction DR5 intersecting the first direction DR1, the second direction DR2, and the fourth direction DR4. The fifth direction DR5 may be diagonal to the first direction DR1 and the second direction DR2. The fifth direction DR5 may be parallel to the first surface 100a. In example embodiments, the magnitude of the angle between the fourth direction DR4 and the second direction DR2 may be substantially the same as the magnitude of the angle between the fifth direction DR5 and the second direction DR2. The first gate electrodes 310 and the second gate electrodes 320 may include an electrically conductive material. For example, the first gate electrodes 310 and the second gate electrodes 320 may include doped polysilicon or metal (e.g., copper (Cu), aluminum (Al), molybdenum (Mo), platinum (Pt), titanium (Ti), tantalum (Ta), tungsten (W), or a combination thereof).

Gate insulating films 124 may be provided between the first gate electrodes 310 and the device active regions 220, and between the second gate electrodes 320 and the device active regions 220, respectively. The gate insulating film 124 may include an electrically insulating material. For example, the gate insulating film 124 may include silicon oxide, silicon nitride, or silicon oxynitride.

Contacts CT and horizontal conductive lines HCL may be provided on the substrate 100. The contacts CT and the horizontal conductive lines HCL may provide electrical connections to various components. For example, the contacts CT and the horizontal conductive lines HCL may provide electrical connections to the pixel active region 210, the ground region 105, the device active region 220, the transfer gate electrode 106g, the first gate electrodes 310, and the second gate electrodes 320. The contacts CT may extend along the third direction DR3. The horizontal conductive lines HCL may, for example, extend along the first direction DR1 or the second direction DR2. The contacts CT and the horizontal conductive lines HCL may include an electrically conductive material. For example, the contacts CT and the horizontal conductive lines HCL may include doped polysilicon or metal (e.g., copper (Cu), aluminum (Al), molybdenum (Mo), platinum (Pt), titanium (Ti), tantalum (Ta), tungsten (W), or a combination thereof).

The first gate electrodes 310 may include a 1a gate electrode 312 (310), a 1b gate electrode 314 (310), a 1c gate electrode 316 (310), and a 1d gate electrode 318 (310). The 1a gate electrode 312 (310) may be provided on the (1,1) device active region 221. The 1b gate electrode 314 (310) may be provided on the (2,1) device active region 223. The 1b gate electrode 314 (310) may be spaced apart from the 1a gate electrode 312 (310) along the first direction DR1. The 1c gate electrode 316 (310) may be provided on the (3,2) device active region 226. The 1d gate electrode 318 (310) may be provided on the (4,2) device active region 228. The 1d gate electrode 318 (310) may be spaced apart from the 1c gate electrode 316 (310) along the first direction DR1.

The second gate electrodes 320 may include a 2a gate electrode 322 (320), a 2b gate electrode 324 (320), a 2c gate electrode 326 (320), and a 2d gate electrode 328 (320). The 2a gate electrode 322 (320) may be provided on the (1,2) device active region 222. The 2a gate electrode 322 (320) may be electrically connected to the floating diffusion regions 104 by the contacts CT and the horizontal conductive lines HCL.

The 2b gate electrode 324 (320) may be provided on the (2,2) device active region 224. The 2b gate electrode 324 (320) may be spaced apart from the 2a gate electrode 322 (320) along the first direction DR1. The 2c gate electrode 326 (320) may be provided on the (3,1) device active region 325. The 2d gate electrode 328 (320) may be provided on the (4,1) device active region 327. The 2d gate electrode 328 (320) may be spaced apart from the 2c gate electrode 326 (320) along the first direction DR1.

The 1a to 2b gate electrodes 312, 322, 314, 324 may be arranged alternately along the first direction DR1. The 1a gate electrode 312 (310) and the 2a gate electrode 322 (320) may become farther apart from each other along the second direction DR2. The 2a gate electrode 322 (320) and the 1b gate electrode 314 (310) may become closer to each other along the second direction DR2. The 1b gate electrode 314 (310) and the 2b gate electrode 324 (320) may become farther apart from each other along the second direction DR2.

The 2c to 1d gate electrodes 326, 316, 328, 318 may be arranged alternately along the first direction DR1. The 2c gate electrode 326 (320) and the 1c gate electrode 316 (310) may become farther apart from each other along the second direction DR2. The 1c gate electrode 316 (310) and the 2d gate electrode 328 (320) may become closer to each other along the second direction DR2. The 2d gate electrode 328 (320) and the 1d gate electrode 318 (310) may become farther apart from each other along the second direction DR2. The 1a to 2b gate electrodes 312, 322, 314, 324 may each be spaced apart from the 2c to 1d gate electrodes 326, 316, 328, 318 along the second direction DR2. a first connecting conductive pattern 331 may be provided between the 1a gate electrode 312 (310) and the 2a gate electrode 322 (320) to electrically connect the 1a gate electrode 312 (310) and the 2a gate electrode 322 (320). For example, the first connecting conductive pattern 331 may extend along the first direction DR1.

The first gate electrodes 310 and the second gate electrodes 320 may constitute the gate electrodes of a source follower transistor, a reset transistor, a select transistor, and a dummy transistor. The 1a gate electrode 312 (310) and the 2a gate electrode 322 (320) may be gate electrodes of the source follower transistors. The 1b gate electrode 314 (310), the 2b gate electrode 324 (320), and the 2d gate electrode 328 (320) may be gate electrodes of the reset transistors. The dummy transistor may be formed on the (4,2) device active region 228. The 1d gate electrode 318 (310) may be the gate electrode of the dummy transistor. The 2c gate electrode 326 (320) and the 1c gate electrode 316 (310) may be gate electrodes of select transistors.

First source/drain regions SD1 and second source/drain regions SD2 may be provided in the device active regions 220. The first source/drain region SD1 and the second source/drain region SD2 may be provided on the top of the substrate 100. The first source/drain region SD1 and the second source/drain region SD2 may have the second conductivity type. Immediately adjacent first source/drain region SD1 and second source/drain region SD2 may be spaced apart from each other with the first gate electrode 310 or the second gate electrode 320 between them. The second source/drain region SD2 may be provided between the first gate electrode 310 and the second gate electrode 320 immediately adjacent along the first direction DR1. The second source/drain region SD2 may be provided on each side of the first gate electrodes 310 and the second gate electrodes 320 facing the connection region 230. The first source/drain region SD1 may be provided on each side of the first gate electrodes 310 and the second gate electrodes 320 facing the opposite side of the connection region 230.

The first source/drain regions SD1 of (1,1) and (1,2) device active regions 221, 222 may be the sources of the source follower transistor. The first source/drain regions SD1 of (3,1) and (3,2) device active regions 225, 226 may be the drains of the select transistor. The first source/drain regions SD1 of (1,1), (1,2), (3,1), and (3,2) device active regions 221, 222, 225, 226 may be electrically connected to each other by the contacts CT and the horizontal conductive lines HCL. In this regard, the source of the source follower transistor and the drain of the select transistor may be electrically connected to each other.

The second source/drain regions SD2 of (1,1) and (1,2) device active regions 221, 222 may be the drains of the source follower transistor. The contact CT may be connected to the connection region 230 between the (1,1) and (1,2) device active regions 221, 222 to apply the second power voltage VDD2 to the second source/drain regions SD2 of (1,1) and (1,2) device active regions 221, 222 (i.e., the drains of the source follower transistor).

The second source/drain regions SD2 of (3,1) and (3,2) device active regions 225, 226 may be the sources of the select transistor. The contact CT may be connected to the connection region 230 between the (3,1) and (3,2) device active regions 225, 226 to output the pixel output voltage from the second source/drain regions SD2 of (3,1) and (3,2) device active regions 225, 226 (i.e., the sources of the select transistor).

The first source/drain region SD1 of (2,1) device active region 223, the second source/drain region SD2 of (2,2) device active region 224, and the second source/drain region SD2 of (4,1) device active region 227 may be the drains of the reset transistors. The second source/drain region SD2 of (2,1) device active region 223, the first source/drain region SD1 of (2,2) device active region 224, and the first source/drain region SD1 of (4,1) device active region 227 may be the sources of the reset transistors.

The reset transistors on the (2,1) device active region 223, the (2,2) device active region 224, and the (4,1) device active region 227 may be connected in series. The second source/drain region SD2 of (2,1) device active region 223 may be electrically connected to the second source/drain region SD2 of (2,2) device active region 224. The first source/drain region SD1 of (2,2) device active region 224 may be electrically connected to the second source/drain region SD2 of (4,1) device active region 227. For example, the first source/drain region SD1 of (2,2) device active region 224 and the second source/drain region SD2 of (4,1) device active region 227 may be electrically connected by a pair of contacts CT, the horizontal conductive line HCL, and the connection region between the (4,1) device active region 227 and the (4,2) device active region 228. The first source/drain region SD1 and the second source/drain region SD2 of (4,2) device active region 228 may be dummy source/drain regions of the dummy transistor. In example embodiments, the contact CT may be placed on the second source/drain region SD2 of (4,2) device active region 228 to provide electrical connection between the first source/drain region SD1 of (2,2) device active region 224 and the second source/drain region SD2 of (4,1) device active region 227.

The contacts CT and the horizontal conductive lines HCL may be connected to the first source/drain region SD1 of (4,1) device active region 227 (i.e., the source of the reset transistor on (4,1) device active region 227). The first source/drain region SD1 of (4,1) device active region 227 may receive an initial voltage (the first power voltage VDD1 described with reference to FIGS. 1 to 3) through the contact CT and the horizontal conductive lines HCL. Voltages may be independently applied to the gates of the reset transistors on (2,1) device active region 223, the (2,2) device active region 224, and the (4,1) device active region 227 (i.e., 1b, 2b, and 2d gate electrodes 314, 324, 328) to apply an initial voltage to the floating diffusion region 104. Applying the initial voltage to the floating diffusion region 104 may be referred to as a reset operation. Voltages applied to the 1b, 2b, and 2d gate electrodes 314, 324, 328 may be applied based on the reset signal described with reference to FIGS. 1 to 3.

A voltage may be applied to the 1a gate electrode 312 (310) and the 2a gate electrode 322 (320) by the charge accumulated in the floating diffusion region 104. The voltage applied to the 1a gate electrode 312 (310) and the 2a gate electrode 322 (320) may be the gate voltage of the source follower transistor.

A voltage may be applied to the 1c and the 2c gate electrodes 316, 326 to apply a pixel output voltage to the second source/drain regions SD2 of (3,1) and (3,2) device active regions 225, 226. The pixel output voltage may be provided to an analog signal processing circuit through the contact CT connected to the connection region 230 between the (3,1) and (3,2) device active regions 225, 226.

A first interlayer insulating film IL1 may be provided on the substrate 100 to cover the transfer gate electrode 106g, the first gate electrodes 310, and the second gate electrodes 320. The first interlayer insulating film IL1 may be penetrated by the contacts CT. The horizontal conductive lines HCL may be provided on the first interlayer insulating film IL1. The first interlayer insulating film IL1 may include an electrically insulating material. For example, the first interlayer insulating film IL1 may include silicon nitride, silicon oxide, silicon oxynitride, or a combination thereof.

A second interlayer insulating film IL2 may be provided on the first interlayer insulating film IL1. The second interlayer insulating film IL2 may cover the horizontal conductive lines HCL. The second interlayer insulating film IL2 may include an electrically insulating material. For example, the second interlayer insulating film IL2 may include silicon nitride, silicon oxide, silicon oxynitride, or a combination thereof.

One of the noises that the image sensor has, Random Telegraph Signal (RTS), may be affected by the planar area of the gate electrode of the source follower transistor. For example, the larger the planar area of the gate electrode of the source follower transistor, the smaller the RTS may be. Because the area where the source and drain are placed within the device active region 220 must be secured, the width of the gate electrode may be limited. Therefore, the planar area of the gate electrode of the source follower transistor may be generally determined by the length of the gate.

The source follower transistor may generally be formed in the device active region 220 with a rectangular shape having boundaries along the first direction DR1 and the second direction DR2. Within a rectangular-shaped device active region 220, a gate electrode extending in a direction intersecting its boundary (e.g., the fourth direction DR4 or the fifth direction DR5) may have a longer length than a gate electrode extending in a direction parallel to its boundary (i.e., the first direction DR1 or the second direction DR2). Therefore, the 1a and 2a gate electrodes 312, 322 extending along the fourth direction DR4 and the fifth direction DR5, respectively, may have a relatively large planar area. Accordingly, an image sensor 10 with low noise may be provided.

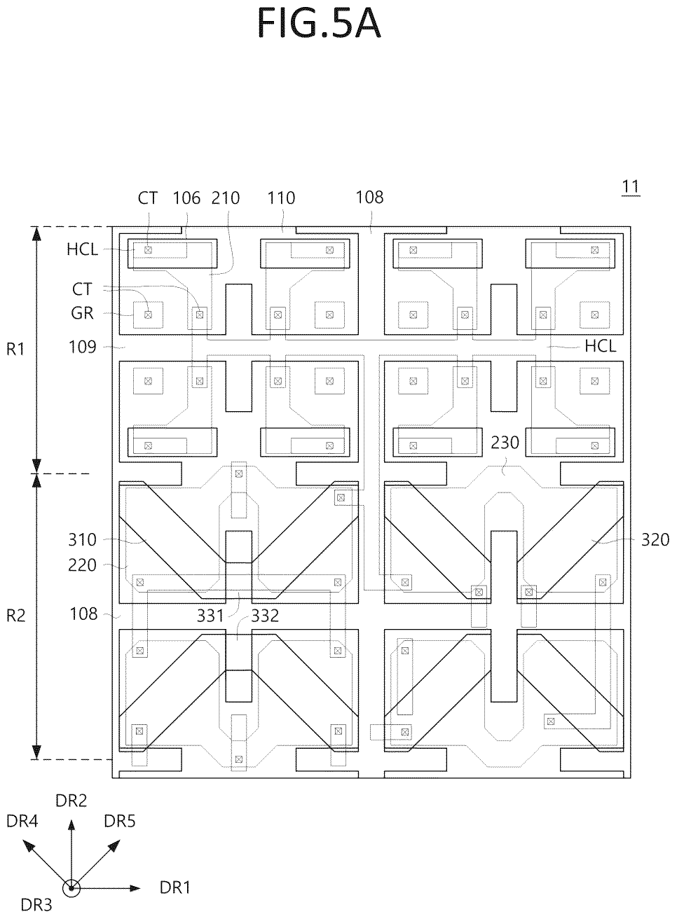

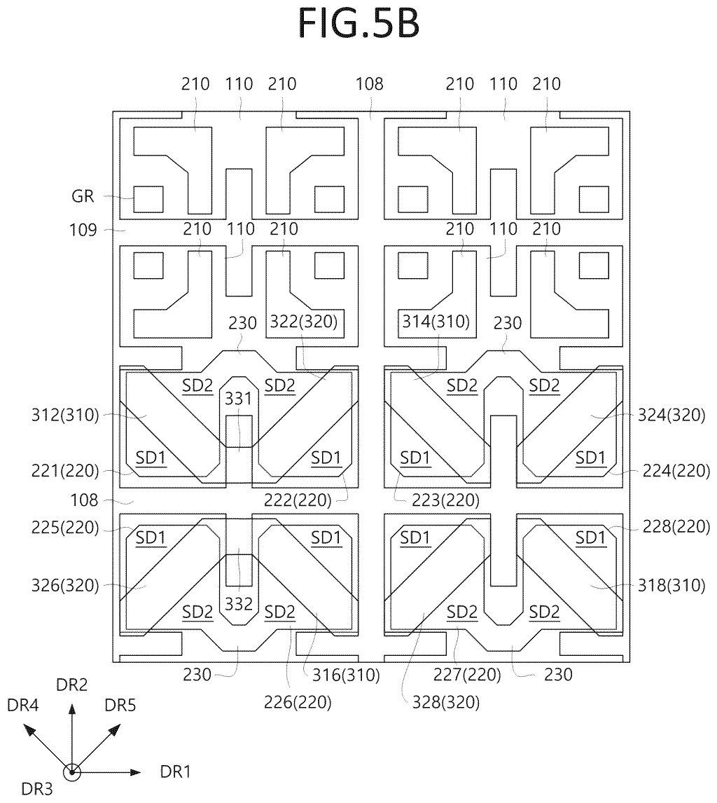

FIG. 5A is a plan view of an image sensor according to example embodiments. FIG. 5B is a plan view for explaining the pixel active region, device active region, first gate electrode, and second gate electrode of FIG. 5A. For the sake of brevity, this disclosure is described focusing on the differences from FIGS. 4A to 4G.

Referring to FIGS. 5A and 5B, a second connecting conductive pattern 332 may be further provided between the 2c gate electrode 326 and the 1c gate electrode 316. For example, the second connecting conductive pattern 332 may extend along the first direction DR1. The 2c gate electrode 326 and the 1c gate electrode 316 may be electrically connected to each other by the second connecting conductive pattern 332. Accordingly, the gates of the select transistors may be electrically connected to each other. As an example, the contacts CT may be connected to the 2c gate electrode 326 and the 1c gate electrode 316, respectively. In other example embodiments, a contact CT may be connected to one of the 2c gate electrode 326 and the 1c gate electrode 316.

According to the present disclosure, an image sensor 11 having low noise may be provided.

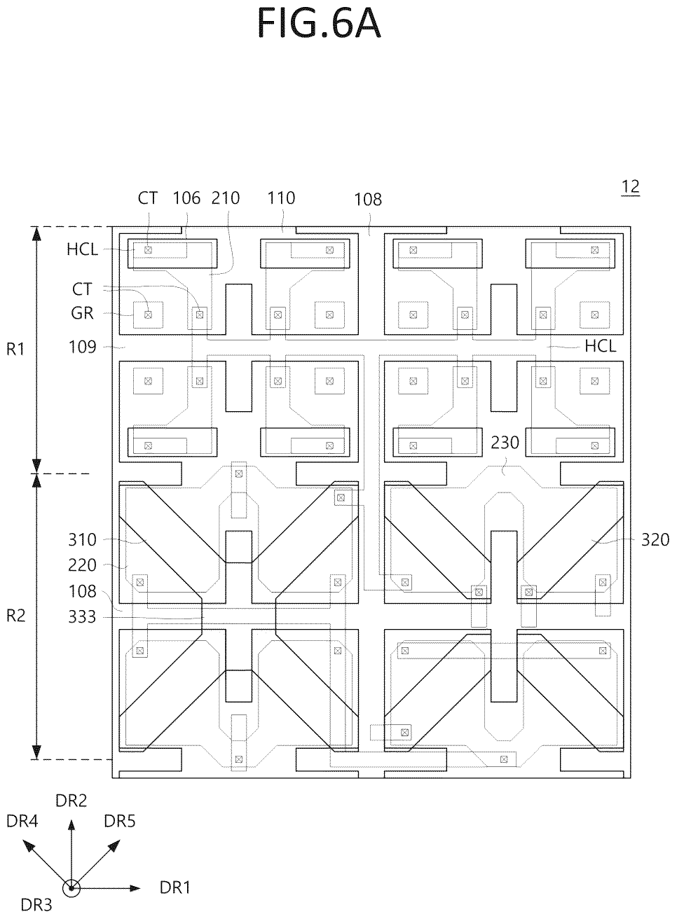

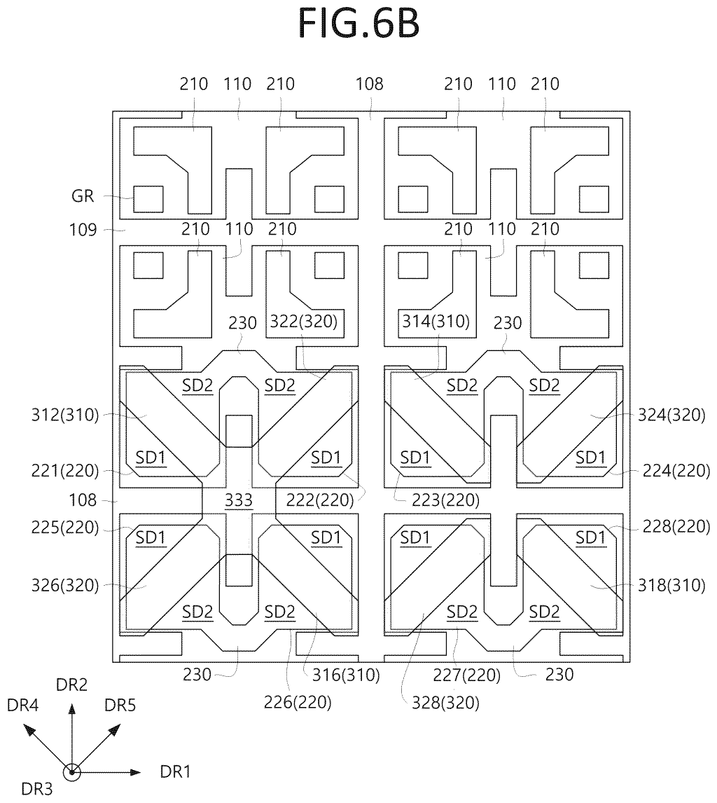

FIG. 6A is a plan view of an image sensor according to example embodiments. FIG. 6B is a plan view for explaining the pixel active region, device active region, first gate electrode, and second gate electrode of FIG. 6A. For the sake of brevity, this disclosure is described focusing on the differences from FIGS. 4A to 4G.

Referring to FIGS. 6A and 6B, source follower transistors may be provided on the (1,1), (1,2), (3,1), and (3,2) device active regions 221, 222, 225, 226, respectively. Select transistors may be provided on the (4,1) device active region 227 and the (4,2) device active region 228, respectively. Reset transistors may be provided on the (2,1) device active region 223 and the (2,2) device active region 224, respectively.

A third connecting conductive pattern 333 may be provided between the 1a gate electrode 312, the 2a gate electrode 322, the 2c gate electrode 326, and the 1c gate electrode 316. The 1a gate electrode 312, the 2a gate electrode 322, the 2c gate electrode 326, and the 1c gate electrode 316 may be electrically connected to each other by the third connecting conductive pattern 333. The 1a gate electrode 312, the 2a gate electrode 322, the 2c gate electrode 326, and the 1c gate electrode 316 may be the gates of the source follower transistor.

The first source/drain regions SD1 of (1,1) device active region 221, (1,2) device active region 222, (3,1) device active region 225, and (3,2) device active region 226 may be the sources of the source follower transistor. The second source/drain regions SD2 of (4,1) device active region 227 and (4,2) device active region 228 may be the drains of the select transistor. The first source/drain regions SD1 of (1,1) device active region 221, (1,2) device active region 222, (3,1) device active region 225, and (3,2) device active region 226 and the connection region 230 between the (4,1) device active region 227 and the (4,2) device active region 228 may be electrically connected to each other by the contacts CT and the horizontal conductive line HCL. The second source/drain regions SD2 of (4,1) device active region 227 and (4,2) device active region 228 may be electrically connected to each other by the connection region 230 between the (4,1) device active region 227 and the (4,2) device active region 228. Accordingly, the first source/drain regions SD1 of (1,1) device active region 221, (1,2) device active region 222, (3,1) device active region 225, and (3,2) device active region 226 and the second source/drain regions SD2 of (4,1) device active region 227 and (4,2) device active region 228 may be electrically connected to each other.

The second source/drain regions SD2 of (1,1) device active region 221, (1,2) device active region 222, (3,1) device active region 225, and (3,2) device active region 226 may be the drains of the source follower transistor. The contact CT may be further connected to the connection region 230 between the (3,1) and (3,2) device active regions 225, 226 to apply the second power voltage VDD2 to the second source/drain regions SD2 of (3,1) and (3,2) device active regions 225, 226 (i.e., the drains of the source follower transistor).

The first source/drain regions SD1 of (4,1) and (4,2) device active regions 227, 228 may be the sources of the select transistor. The contacts CT may be connected to the first source/drain regions SD1 of (4,1) and (4,2) device active regions 227, 228 to output the pixel output voltage.

According to the present disclosure, an image sensor 12 having low noise may be provided.

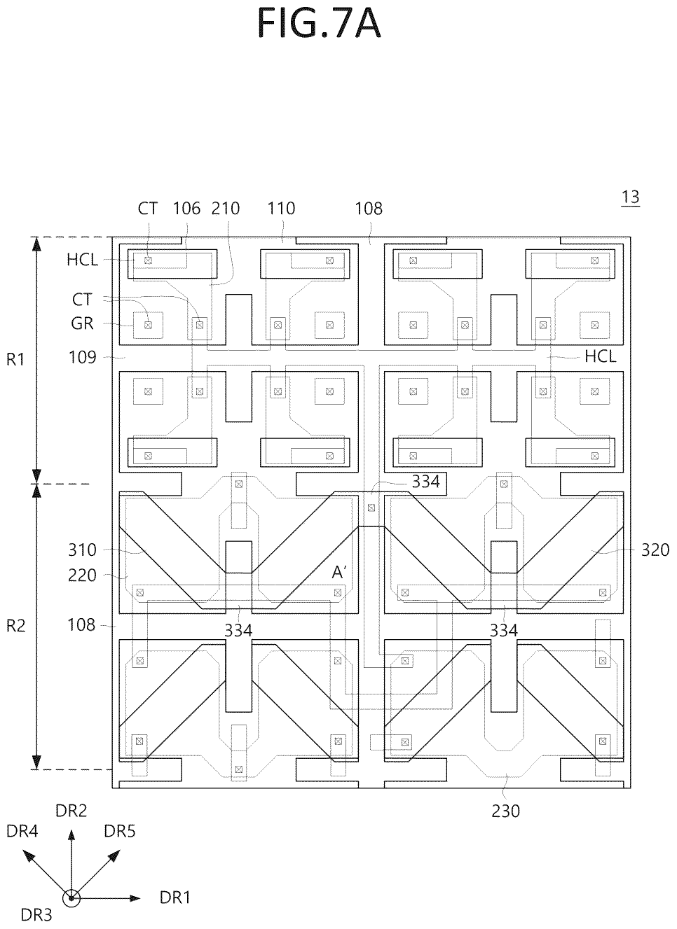

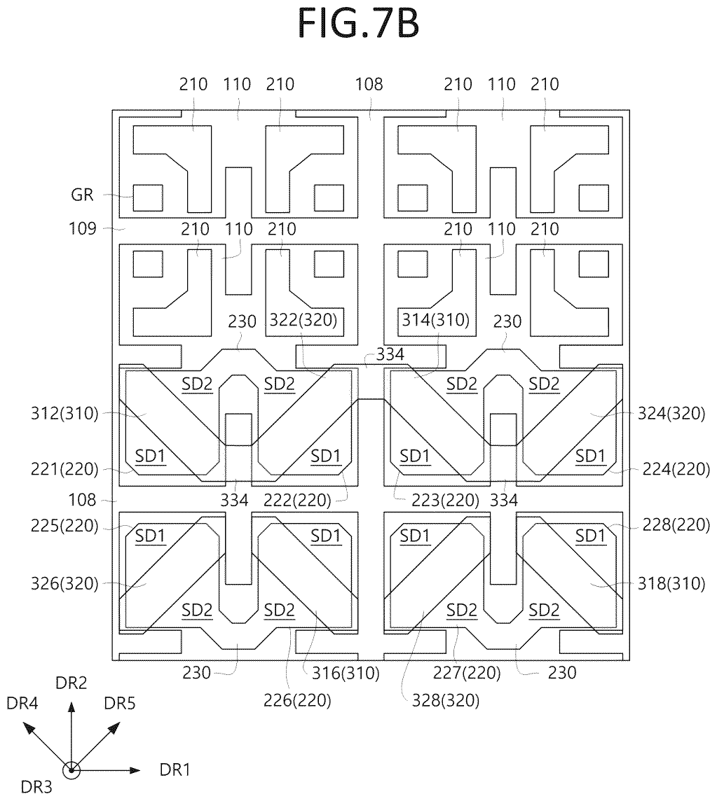

FIG. 7A is a plan view of an image sensor according to example embodiments. FIG. 7B is a plan view for explaining the pixel active region, device active region, first gate electrode, and second gate electrode of FIG. 7A. For the sake of brevity, this disclosure is described focusing on the differences from FIGS. 4A to 4G.

Referring to FIGS. 7A and 7B, source follower transistors may be provided on the (1,1), (1,2), (2,1), and (2,2) device active regions 220, respectively. Select transistors may be provided on the (3,1) device active region 225 and the (3,2) device active region 226, respectively. Reset transistors may be provided on the (4,1) device active region 227 and the (4,2) device active region 228, respectively.

Fourth connecting conductive patterns 334 may be provided between the 1a gate electrode 312 and the 2a gate electrode 322, between the 2a gate electrode 322 and the 1b gate electrode 314, and between the 1b gate electrode 314 and the 2b gate electrode 324, respectively. The 1a gate electrode 312, the 2a gate electrode 322, the 1b gate electrode 314, and the 2b gate electrode 324 may be electrically connected in sequence by the fourth connecting conductive patterns 334. The 1a gate electrode 312, the 2a gate electrode 322, the 1b gate electrode 314, and the 2b gate electrode 324 may be the gates of the source follower transistor.

The first source/drain regions SD1 of (1,1) device active region 221, (1,2) device active region 222, (2,1) device active region 223, and (2,2) device active region 224 may be the sources of the source follower transistor. The second source/drain regions SD2 of (1,1) device active region 221, (1,2) device active region 222, (2,1) device active region 223, and (2,2) device active region 224 may be the drains of the source follower transistor.

The first source/drain regions SD1 of (3,1) device active region 225 and (3,2) device active region 226 may be the drains of the select transistor. The first source/drain regions SD1 of (1,1) device active region 221, (1,2) device active region 222, (2,1) device active region 223, and (2,2) device active region 224 and the first source/drain regions SD1 of (3,1) device active region 225 and (3,2) device active region 226 may be electrically connected to each other by the contacts CT and the horizontal conductive lines HCL.

The second source/drain regions SD2 of (3,1) device active region 225 and (3,2) device active region 226 may be electrically connected to each other by the connection region 230 between (3,1) device active region 225 and (3,2) device active region 226. The contact CT may be connected to the connection region 230 between the (3,1) and (3,2) device active regions 225, 226 to output the pixel output voltage from the second source/drain regions SD2 of (3,1) and (3,2) device active regions 225, 226 (i.e., the sources of the select transistor).

The first source/drain region SD1 of (4,1) device active region 227 and the second source/drain region SD2 of (4,2) device active region 228 may be the drains of the reset transistors. The second source/drain region SD2 of (4,1) device active region 227 and the first source/drain region SD1 of (4,2) device active region 228 may be the sources of the reset transistors. The first source/drain region SD1 of (4,1) device active region 227 may be electrically connected to the floating diffusion region 104 through the contacts CT and the horizontal conductive lines HCL. The first source/drain region SD1 of (4,2) device active region 228 may receive an initial voltage (the first power voltage VDD1 described with reference to FIGS. 1 to 3) through the contacts CT and the horizontal conductive lines HCL. Voltages may be independently applied to the 2d and 1d gate electrodes 328, 318 to apply an initial voltage to the floating diffusion region 104. Applying the initial voltage to the floating diffusion region 104 may be referred to as a reset operation. The voltages applied to the 2d and 1d gate electrodes 328, 318 may be applied based on the reset signal described with reference to FIGS. 1 to 3.

According to the present disclosure, an image sensor 13 having low noise may be provided.

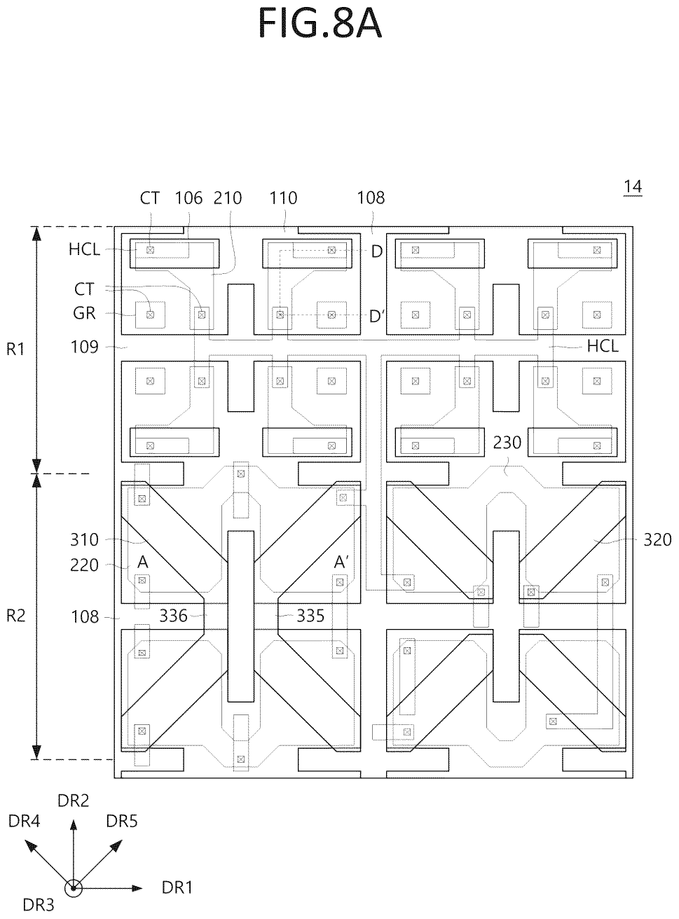

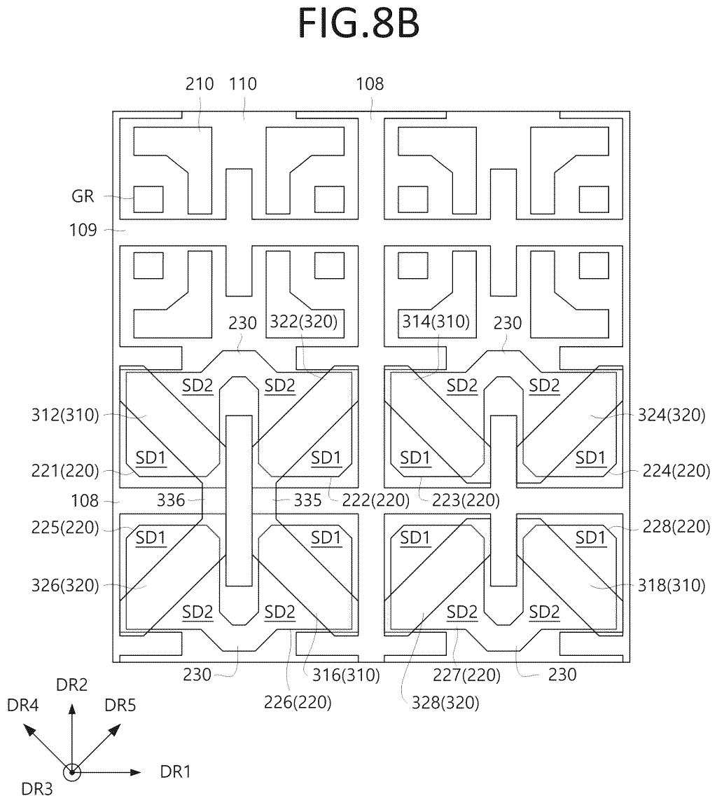

FIG. 8A is a plan view of an image sensor according to example embodiments. FIG. 8B is a plan view for explaining the pixel active region, device active region, first gate electrode, and second gate electrode of FIG. 8A. For the sake of brevity, this disclosure is described focusing on the differences from FIGS. 4A to 4G.

Referring to FIGS. 8A and 8B, source follower transistors may be provided on the (1,2) and (3,2) device active regions 222, 226, respectively. Select transistors may be provided on the (1,1) device active region 221 and (3,1) device active region 225, respectively. Reset transistors may be provided on (4,1) device active region 227 and (4,2) device active region 228, respectively.

The 2a gate electrode 322 and the 1c gate electrode 316 may be the gates of the source follower transistor. A fifth connecting conductive pattern 335 may be provided between the 2a gate electrode 322 and the 1c gate electrode 316. The 2a gate electrode 322 and the 1c gate electrode 316 may be electrically connected by the fifth connecting conductive pattern 335.

The second source/drain regions SD2 of (1,2) device active region 222 and (3,2) device active region 226 may be the sources of the source follower transistor. The first source/drain regions SD1 of (1,2) device active region 222 and (3,2) device active region 226 may be the drains of the source follower transistor.

The 1a gate electrode 312 and the 2c gate electrode 326 may be the gates of the select transistor. A sixth connecting conductive pattern 336 may be provided between the 1a gate electrode 312 and the 2c gate electrode 326. The 1a gate electrode 312 and the 2c gate electrode 326 may be electrically connected by the sixth connecting conductive pattern 336.

The second source/drain regions SD2 of (1,1) device active region 221 and (3,1) device active region 225 may be the drains of the select transistor. The second source/drain region SD2 of (1,1) device active region 221 and the second source/drain region SD2 of (1,2) device active region 222 may be electrically connected to each other by the connection region 230 between the (1,1) device active region 221 and the (1,2) device active region 222. The second source/drain region SD2 of (3,1) device active region 225 and the second source/drain region SD2 of (3,2) device active region 226 may be electrically connected to each other by the connection region 230 between (3,1) device active region 225 and (3,2) device active region 226.

The first source/drain regions SD1 of (1,1) device active region 221 and (3,1) device active region 225 may be the sources of the select transistor. The contacts CT may be connected to the first source/drain regions SD1 of (1,1) device active region 221 and (3,1) device active region 225 respectively to output the pixel output voltage from the first source/drain regions SD1 of (1,1) device active region 221 and (3,1) device active region 225 (i.e., the sources of the select transistor).

Reset transistors may be provided on the (2,1), (2,2), and (4,1) device active regions 223, 224, 227. The reset transistors may be substantially the same as those described with reference to FIGS. 4A to 4G.

According to the present disclosure, an image sensor 14 having low noise may be provided.

In some example embodiments, each of the components represented by a block as illustrated in FIG. 1 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of example embodiments have been described, it will be apparent to those of ordinary skill in the art that various changes and modifications may be made thereto without departing from the spirit and scope of the following claims.

What is claimed is:

1. An image sensor comprising:
a substrate comprising a first region in which a photoelectric conversion region is provided, and a second region in which a first device active region and a second device active region are arranged along a first direction;
a first gate electrode provided on the first device active region;
a second gate electrode provided on the second device active region; and
a first connecting conductive pattern provided between the first gate electrode and the second gate electrode,
wherein a distance between the first gate electrode and the second gate electrode increases along a second direction perpendicular to the first direction.

2. The image sensor of claim 1, wherein the first gate electrode extends along a third direction intersecting the first direction and the second direction,
wherein the second gate electrode extends along a fourth direction intersecting the first direction, the second direction and the third direction,
wherein the first device active region comprises a first source/drain region and a second source/drain region spaced apart from each other with the first gate electrode therebetween, and
wherein the second device active region comprises a third source/drain region and a fourth source/drain region spaced apart from each other with the second gate electrode therebetween.

3. The image sensor of claim 2, wherein the substrate further comprises a connection region provided between the first device active region and the second device active region, and
wherein the connection region electrically connects the second source/drain region and the fourth source/drain region.

4. The image sensor of claim 1, wherein the substrate further comprises a connection region provided between the first device active region and the second device active region, and
wherein at least a portion of the connection region is offset from the first device active region and the second device active region along the first direction.

5. The image sensor of claim 1, further comprising a third gate electrode and a fourth gate electrode,
wherein the third gate electrode is provided between the second gate electrode and the fourth gate electrode along the first direction,
wherein the substrate further comprises a third device active region and a fourth device active region facing the third gate electrode and the fourth gate electrode, respectively,
wherein a distance between the second gate electrode and the third gate electrode decreases along the second direction, and
wherein a distance between the third gate electrode and the fourth gate electrode increases other along the second direction.

6. The image sensor of claim 5, further comprising:
a second connecting conductive pattern provided between the second gate electrode and the third gate electrode; and
a third connecting conductive pattern provided between the third gate electrode and the fourth gate electrode,
wherein the first gate electrode, the second gate electrode, the third gate electrode and the fourth gate electrode are electrically connected by the first connecting conductive pattern, the second connecting conductive pattern and the third connecting conductive pattern.

7. The image sensor of claim 5, wherein the third device active region comprises a fifth source/drain region provided between the second gate electrode and the third gate electrode, and a sixth source/drain region spaced apart from the fifth source/drain region with the third gate electrode therebetween,
wherein the substrate further comprises a floating diffusion region provided in the first region and configured to receive charge carriers from the photoelectric conversion region, and
wherein the floating diffusion region is electrically connected to the second gate electrode and the fifth source/drain region.

8. The image sensor of claim 1, further comprising:
a fifth gate electrode and a sixth gate electrode provided on the substrate,
wherein the substrate further comprises a fifth device active region and a sixth device active region facing the fifth gate electrode and the sixth gate electrode, respectively,
wherein the first gate electrode and the second gate electrode are spaced apart from the fifth gate electrode and the sixth gate electrode along the second direction, respectively, and
wherein a distance between the fifth gate electrode and the sixth gate electrode decreases along the second direction.

9. The image sensor of claim 8, further comprising a fourth connecting conductive pattern provided between the first gate electrode, the second gate electrode, the fifth gate electrode, and the sixth gate electrode,
wherein the first gate electrode, the second gate electrode, the fifth gate electrode, and the sixth gate electrode are electrically connected to each other by the fourth connecting conductive pattern.

10. The image sensor of claim 8, further comprising a fifth connecting conductive pattern provided between the fifth gate electrode and the sixth gate electrode,
wherein the fifth gate electrode and the sixth gate electrode are electrically connected to each other by the fifth connecting conductive pattern.

11. The image sensor of claim 8, further comprising a seventh gate electrode and an eighth gate electrode aligned with the sixth gate electrode along the first direction,
wherein the seventh gate electrode is provided between the sixth gate electrode and the eighth gate electrode along the first direction,
wherein the substrate further comprises a seventh device active region facing the seventh gate electrode, and an eighth device active region facing the eighth gate electrode,
wherein a distance between the seventh gate electrode and the eighth gate electrode decreases other along the second direction, and
wherein a distance between the sixth gate electrode and the seventh gate electrode increases along the second direction.

12. The image sensor of claim 11, further comprising:
a third gate electrode and a fourth gate electrode,
wherein the third gate electrode is provided between the second gate electrode and the fourth gate electrode along the first direction,
wherein the substrate further comprises a floating diffusion region provided in the first region and configured to receive charge carriers from the photoelectric conversion region, a third device active region facing the third gate electrode, and a fourth device active region facing the fourth gate electrode,
wherein the third device active region comprises a third source/drain region provided between the second gate electrode and the third gate electrode and electrically connected to the floating diffusion region, and a fourth source/drain region provided between the third gate electrode and the fourth gate electrode,
wherein the fourth device active region comprises a fifth source/drain region provided between the third gate electrode and the fourth gate electrode, and a sixth source/drain region provided between the fourth gate electrode and the eighth gate electrode, and
wherein the seventh device active region comprises a seventh source/drain region provided between the sixth gate electrode and the seventh gate electrode, and an eighth source/drain region provided between the seventh gate electrode and the eighth gate electrode, and electrically connected to the sixth source/drain region.

13. The image sensor of claim 1, wherein the substrate further comprises a plurality of pixel active regions arranged along the first direction and the second direction in the first region, a first isolation layer provided between immediately adjacent pixel active regions along the first direction among the plurality of pixel active regions, and a second isolation layer provided between immediately adjacent pixel active regions along the second direction among the plurality of pixel active regions, and
wherein the second isolation layer extends to a shallower depth than the first isolation layer within the substrate.

14. An image sensor comprising:
a plurality of photoelectric conversion regions arranged along intersecting first and second directions;
a plurality of transfer gate electrodes provided on the plurality of photoelectric conversion regions, respectively;
a plurality of floating diffusion regions adjacent to the plurality of transfer gate electrodes, respectively;
first and second source follower transistors arranged along the first direction; and
a first connecting conductive pattern provided between the first source follower transistor and the second source follower transistor, and electrically connecting a first gate electrode of the first source follower transistor and a second gate electrode of the second source follower transistor,
wherein a distance between the first gate electrode and the second gate electrode increases along the second direction,
wherein drains of the first source follower transistor and the second source follower transistor are provided between the first gate electrode and the second gate electrode, and are electrically connected to the plurality of floating diffusion regions, and
wherein sources of the first source follower transistor and the second source follower transistor are spaced apart from the drains with the first gate electrode and the second gate electrode therebetween, respectively.

15. The image sensor of claim 14, further comprising a first selection transistor and a second selection transistor arranged along the first direction,
wherein the first source follower transistor is spaced apart from the first selection transistor along the second direction, and the second source follower transistor is spaced apart from the second selection transistor along the second direction,
wherein a distance between the first gate electrode and the second gate electrode decreases along the second direction, and
wherein drains of the first and second selection transistors are electrically connected to the sources of the first and second source follower transistors.

16. The image sensor of claim 15, further comprising:
a first reset transistor aligned with the second source follower transistor along the first direction;
a second reset transistor aligned with the second source follower transistor along the first direction, wherein the first reset transistor is between the second source follower transistor and the second reset transistor; and
a third reset transistor spaced apart from the second selection transistor along the first direction,
wherein the first reset transistor is spaced apart from the third reset transistor along the second direction,
wherein a drain of the first reset transistor is electrically connected to the plurality of floating diffusion regions,
wherein a source of the first reset transistor and a drain of the second reset transistor are electrically connected to each other, and
wherein a source of the second reset transistor and a drain of the third reset transistor are electrically connected to each other.

17. The image sensor of claim 16, further comprising a dummy transistor provided between the second reset transistor and the third reset transistor, and comprising a dummy gate electrode, a first dummy source/drain, and a second dummy source/drain,
wherein the first dummy source/drain is between the dummy gate electrode and a gate electrode of the second reset transistor,
wherein the second dummy source/drain is between the dummy gate electrode and a gate electrode of the third reset transistor, and
wherein the source of the second reset transistor is electrically connected to the second dummy source/drain.

18. The image sensor of claim 14, further comprising:
a third source follower transistor and a fourth source follower transistor aligned with the second source follower transistor along the first direction, wherein the third source follower transistor is between the second source follower transistor and the fourth source follower transistor;
a second connecting conductive pattern provided between the second source follower transistor and the third source follower transistor; and
a third connecting conductive pattern provided between the third source follower transistor and the fourth source follower transistor,
wherein a distance between gate electrodes of the third source follower transistor and the fourth source follower transistor increases along the second direction,
wherein a distance between the gate electrodes of the second source follower transistor and the third source follower transistor decreases along the second direction, and
wherein drains of the third source follower transistor and the fourth source follower transistor are provided between the gate electrodes of the third source follower transistor and the fourth source follower transistor, and are electrically connected to the plurality of floating diffusion regions.

19. The image sensor of claim 14, further comprising:
a plurality of pixel active regions provided on the plurality of photoelectric conversion regions, respectively;
a first isolation layer provided between immediately adjacent pixel active regions along the first direction among the plurality of pixel active regions; and
a second isolation layer provided between immediately adjacent pixel active regions along the second direction among the plurality of pixel active regions,
wherein the second isolation layer is shallower than the first isolation layer along a third direction perpendicular to the first and second directions.

20. An image sensor comprising:
a plurality of pixels arranged along intersecting first and second directions;
first and second source follower transistors configured to be controlled by a gate voltage that is based on charge carriers provided from the plurality of pixels; and
a connecting conductive pattern provided between the first and second source follower transistors, and electrically connecting gate electrodes of the first and second source follower transistors,
wherein a distance between the gate electrodes of the first and second source follower transistors increases along the second direction,
wherein drains of the first and second source follower transistors are provided between the gate electrodes, and
wherein sources of the first and second source follower transistors are spaced apart from the drains with the gate electrodes therebetween, respectively.
